(19) United States
(12) Patent Application Publication
(10) Pub. No.: US 2018/0364304 A1
(43) Pub. Date: Dec. 20, 2018

(54) STIMULUS GENERATION FOR COMPONENT-LEVEL VERIFICATION

(71) Applicant: SanDisk Technologies LLC, Plano, TX (US)

(72) Inventors: NAMAN RASTOGI, Bareilly (IN); BHAVADIP SOLANKI, Jungadh (IN); SURESH HOSUDI SHANKARA NAIK, Shivamogga (IN)

(73) Assignee: SanDisk Technologies LLC, Plano, TX (US)

(21) Appl. No.: 15/623,275

(22) Filed: Jun. 14, 2017

(51) Int. Cl. G01R 31/3177; G01R 31/317; G06F 17/50

(52) U.S. Cl. CPC G01R 31/3177; G06F 17/5022; G01R 31/31704

(57) ABSTRACT

Apparatuses, systems, methods, and computer program products are disclosed for stimulus generation for component-level verification. A method includes monitoring one or more internal signals for one or more components of a chip during a full-chip verification process. A method includes generating one or more stimuli for triggering one or more internal signals during verification of one or more components of a chip. Stimuli may be generated based in part on feedback from a full-chip verification process. A method includes verifying an operating state of one or more components of a chip in response to generated stimuli that trigger one or more internal signals during verification of the one or more components.

### TECHNICAL FIELD

The present disclosure, in various embodiments, relates to testing integrated circuit devices and more particularly relates to using feedback from a full-chip verification process to test components of the chip.

### BACKGROUND

Integrated circuits (“ICs”) may comprise various components, modules, or sub-units, that perform various operations of the ICs. Further, design and/or operation testing for the IC may occur at the IC level, e.g., to test the operations of the IC, or at the component level, e.g., to test the operations of the various components of the IC. Generating valid stimuli for testing the IC and/or the various components of the IC may ensure maximum verification coverage of the IC and/or the various components during testing.

### SUMMARY

Methods are presented for stimulus generation for component-level verification. In one embodiment, a method includes monitoring one or more internal signals for one or more components of a chip during a full-chip verification process. A method, in certain embodiments, includes generating one or more stimuli for triggering one or more internal signals during verification of one or more components of a chip. Stimuli may be generated based in part on feedback from a full-chip verification process. A method, in various embodiments, includes verifying an operating state of one or more components of a chip in response to generated stimuli that trigger one or more internal signals during verification of the one or more components.

Apparatuses are presented to generate stimulus for component-level verification. In one embodiment, an apparatus includes means for detecting one or more signals for one or more sub-units of an integrated circuit (“IC”) during a design verification test of the IC. In certain embodiments, an apparatus includes means for collecting data during a design verification test of an IC that indicates one or more conditions associated with the IC that trigger one or more signals for one or more sub-units of the IC. In various embodiments, an apparatus includes means for testing one or more operations of one or more sub-units of an IC in response to triggering one or more signals for the one or more sub-units based on one or more stimuli that are generated as a function of condition data that is collected during a design verification test of the IC.

Computer program products comprising a computer readable storage medium are presented. In certain embodiments, a computer readable storage medium stores computer usable program code executable to perform operations for stimulus generation for component-level verification. In one embodiment, an operation includes identifying one or more signals that trigger one or more operations of one or more execution elements of an integrated circuit chip during testing of one or more operations of the integrated circuit chip. In certain embodiments, an operation includes determining one or more properties for triggering one or more signals for one or more execution elements of an integrated circuit chip based on results of testing one or more operations of the integrated circuit chip. In various embodiments, an operation includes generating one or more scenarios based on one or more determined properties for triggering one or more signals of one or more execution elements of an integrated circuit chip to verify one or more operations of the one or more execution elements.

### BRIEF DESCRIPTION OF THE DRAWINGS

A more particular description is included below with reference to specific embodiments illustrated in the appended drawings. Understanding that these drawings depict only certain embodiments of the disclosure and are not therefore to be considered to be limiting of its scope, the disclosure is described and explained with additional specificity and detail through the use of the accompanying drawings, in which:

FIG. 1 is a schematic block diagram of one embodiment of a system for generating stimuli for component-level verification;

FIG. 2 is a schematic block diagram illustrating one embodiment of an integrated circuit design;

FIG. 3 is a schematic block diagram illustrating one embodiment of a component verification module;

FIG. 4 is a schematic block diagram illustrating another embodiment of a component verification module;

FIG. 5 is a schematic flow chart diagram illustrating one embodiment of a method for generating stimuli for component-level verification; and

FIG. 6 is a schematic flow chart diagram illustrating an embodiment of another method for generating stimuli for component-level verification.

### DETAILED DESCRIPTION

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “circuit,” “module,” “apparatus,” or “system.” Furthermore, aspects of the present disclosure may take the form of a computer program product embodied in one or more non-transitory computer readable storage media storing computer readable and/or executable program code.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices, or the like.

Modules may also be implemented at least partially in software for execution by various types of processors. An identified module of executable code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of executable code may include a single instruction, or many instructions, and may even be distributed over several different code segments, among different programs, across several memory devices, or the like. Where a module or portions of a module are implemented in software, the software portions may be stored on one or more computer readable and/or executable storage media. Any combination of one or more computer readable storage media may be utilized. A computer readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may alternatively be embodied by or implemented as a component.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

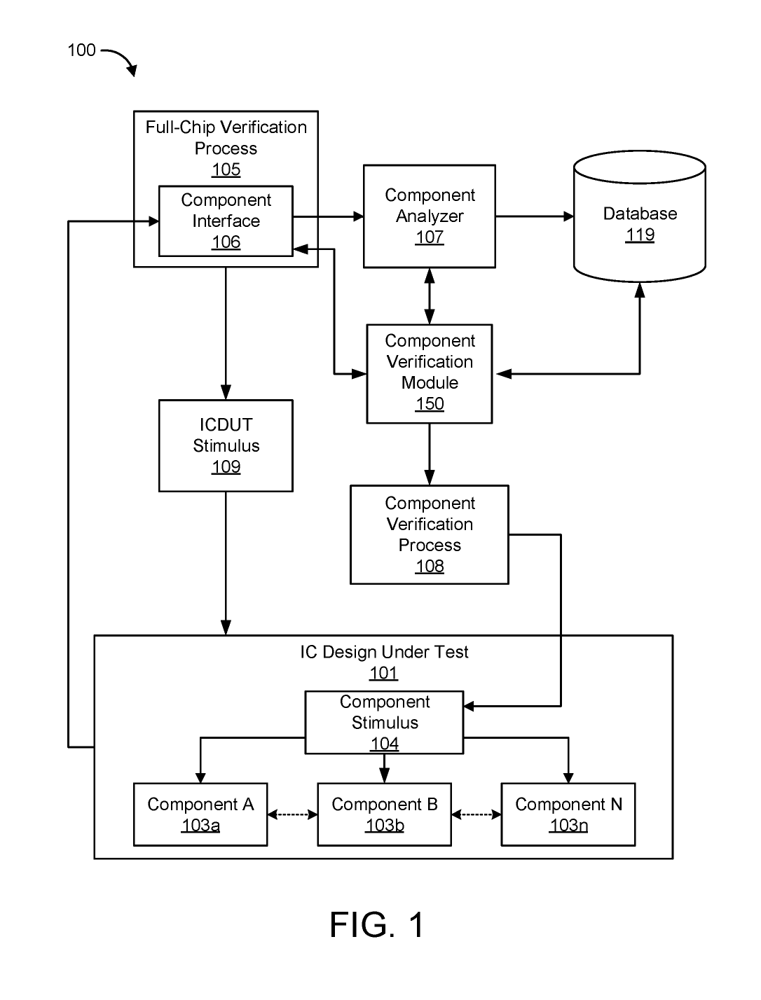

FIG. 1 is a schematic block diagram illustrating one embodiment of a system 100 for generating stimuli for component-level verification. In one embodiment, the system 100 includes one or more integrated circuit (“IC”) designs under test (“DUT”) 101, which includes one or more components 103a-n and one or more component stimuli 104. The system 100, in some embodiments, also includes one or more full-chip verification processes 105, one or more component interfaces 106, one or more component analyzers 107, one or more component verification processes 108, one or more ICDUT stimuli 109, one or more databases 119, and/or one or more component verification modules 150.

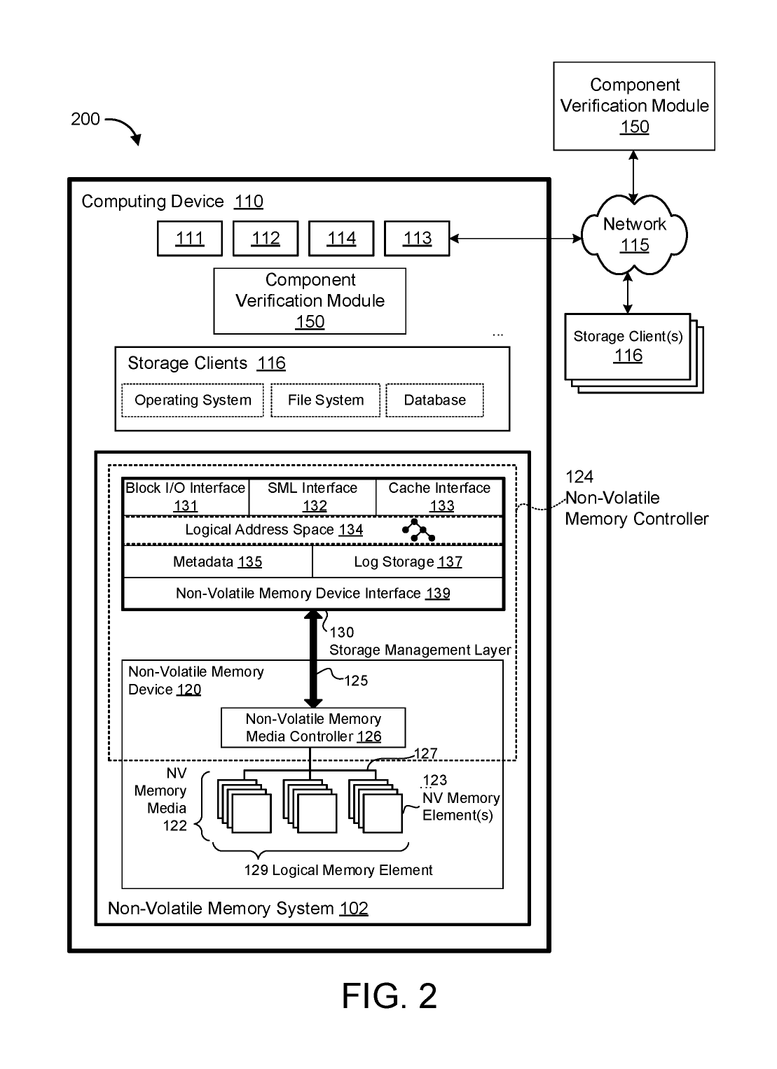

In one embodiment, the one or more ICDUTs 101, as described in more detail below with reference to FIG. 2, comprise a design of an integrated circuit, such as a memory device, a processor, a storage device, a network card, and/or the like. In certain embodiments, the ICDUT 101 comprises designs for a plurality of components of a system such as a computer, a server, a mobile device, and/or the like. One of skill in the art will recognize, in light of this disclosure, the various integrated circuits that may be tested according to the subject matter disclosed herein.

The ICDUTs 101, in certain embodiments, include one or more components 103a-n, sub-units, execution elements, and/or the like that are configured to perform various operations, functions, steps, instructions, commands, and/or the like of the ICDUT 101. The components 103a-n may be embodied as hardware elements, e.g., chips, dies, or the like that are located on the same die or die plane of the ICDUT 101 and may be electrically connected to one or more other components 103a-n of the ICDUT 101, one or more pins for receiving and sending electrical signals, and/or the like. In certain embodiments, the components 103a-n may comprise firmware, software, or a combination of hardware and software for the ICDUT 101. One of skill in the art will recognize the various embodiments of the components 103a-n of the ICDUT 101.

The full-chip verification process 105, in one embodiment, comprises one or more tests, such as operation tests, functionality tests, design tests, or the like tests that are configured to test one or more behaviors, functions, operations, and/or the like of the ICDUT 101. The tests for the full-chip verification process 105 may comprise a sequence of commands, signals, instructions, events, or the like that are configured to trigger signals, conditions, functions, or the like associated with the various behaviors, functions, operations, and/or the like of the ICDUT 101. The full-chip verification process 105 may include code files, text files, configuration files, and/or the like that describe or define the functions, operations, signals, events, and/or the like, and/or an execution sequence, for testing the various operations of the ICDUT 101.

In one embodiment, the ICDUT stimulus 109 triggers the sequence of commands, signals, instructions, events, or the like of the verification test. The full-chip verification process 105, for example, may generate, create, trigger, or the like stimuli 109 for triggering signals associated with testing one or more operations of the ICDUT 101. The signals may include external electrical triggers, or the like, that act as inputs into the ICDUT 101 for performing one or more actions or operations of the ICDUT 101. For example, the ICDUT stimulus 109 may include a signal that sets the mode of the ICDUT 101 (e.g., read/write mode), a signal for the clock/clock rate, and/or signals for data, addresses, and/or the like that are associated with the mode of the ICDUT 101. Accordingly, when the ICDUT stimuli 109 are triggered during the full-chip verification process 105, the various components 103a-n of the ICDUT 101 may perform various functions that cause various internal signals to be triggered, as described in more detail below.

In one embodiment, the component interface 106 monitors the various internal signals that are associated with the components 103a-n during the full-chip verification process 105 for the ICDUT 101. For example, the component interface 106 may snoop, sniff, read, intercept, or the like feedback from the full-test verification process 105 during testing of the ICDUT 101. The feedback may include mode signals for the ICDUT 101, clock signals for the ICDUT 101, timing signals that indicate when certain signals are triggered while testing the ICDUT 101, commands and/or data associated with certain signals, identifiers for components 103a-n of the ICDUT 101 that sent and/or received internal signals and/or the internal signals that were sent and/or received for each component 103a-n, and/or the like. The feedback may be provided for the ICDUT 101 as a whole and/or for each component 103a-n separately, e.g., the component interface 106 may monitor the input/output internal signals to for each component 103a-n, for one or more specified components 103a-n, and/or the like.

The component analyzer 107, in one embodiment, is configured to analyze the feedback from the full-chip verification process 105 of the ICDUT 101. In particular, in certain embodiments, the component analyzer 107 analyzes the feedback as it relates to one or more components 103a-n of the ICDUT 101, which may include signal information/data for the internal signals associated with the components 103a-n. The component analyzer 107, in one embodiment, comprises a universal verification methodology (“UVM”) for analyzing and verifying the signal information for the components 103a-n as monitored by the component interface 106.

In certain embodiments, the component analyzer 107 is configured to generate output from the analysis of the component interface 106, which may include information for generating one or more stimuli 104 for triggering various signals for the components 103a-n, one or more coverage scenarios for testing various operations of the components 103a-n, and/or the like. The component analyzer 107 may store the output from the analysis of the component interface 106 in a database 119. The output may be stored as raw data in a database, as a log file, as an XML or other structured file, and/or the like. The database 119 may comprise a relational database or some other data store.

In one embodiment, the component verification module 150 monitors one or more internal signals for the one or more components 103a-n of the ICDUT 101 during the full-chip verification process 105. In certain embodiments, the component verification module 150 uses the component interface 106 to monitor the internal signals, receives information from the component interface 106 related to monitoring of the internal signals, and/or the like. In a further embodiment, the component interface 106 is part of or is otherwise in communication with the component verification module 150.

In certain embodiments, the component verification module 150, based on the feedback from the full-chip verification process 105, generates one or more component stimuli 104 for triggering one or more internal signals associated with a component 103a-n during component-level verification, e.g., during testing of one or more of the components 103a-n. The component stimuli 104, for example, may include electrical signals, instructions, commands, or the like for triggering external signals for the ICDUT 101, for triggering internal signals for the one or more components 103a-n, for setting chip modes, for triggering clock sequences, and/or the like.

In a further embodiment, the component verification module 150 receives the feedback from the full-chip verification process 105 from the database 119 to use for generating the one or more component stimuli 104 for testing the components 103a-n of the ICDUT 101. As described above, in one embodiment, the component analyzer 107 processes the feedback from the full-chip verification process 105 and stores the results in a data store such as the database 119. The component verification module 150 may have access to the data in the database 119, which may be indexed by component, by particular signals or signal types, by operating mode, by clock time, and/or the like.

The component verification module 150, in a further embodiment, verifies an operating state of a component 103a-n that is being tested based on the generated component stimuli 104. In a further embodiment, the component verification module 150 verifies one or more behaviors, functions, outputs, results, and/or the like of the components 103a-n during component-level testing. The component level testing may be performed by a component verification process 108, which may comprise one or more tests, such as operation, functionality, design, or the like tests that are configured to test one or more behaviors, functions, operations, and/or the like of the components 103a-n. The tests for the component verification process 108 may comprise a sequence of commands, signals, instructions, events, or the like that are configured to trigger signals, conditions, functions, or the like associated with the various behaviors, functions, operations, and/or the like of the components 103a-n. The component verification process 108 may include code files, text files, configuration files, and/or the like that describe or define the functions, operations, signals, events, and/or the like, and/or an execution sequence, for testing the various operations of the components 103a-n.

Thus, in certain embodiments, the component verification module 150 provides an improvement over conventional chip verification methodologies because the component verification module 150 can automatically generate stimuli and coverage scenarios in real-time for testing components 103a-n of a chip based on feedback from verification testing of the chip as a whole. In this manner, there is “communication” between the full-chip verification process 105 and the component verification process 108 in the sense that the component verification process 108 can use feedback, information, data, and/or the like from the full-chip verification process 105 to generate valid and accurate stimuli for providing more comprehensive verification testing and analysis of the components 103a-n.

FIG. 2 is a block diagram of one embodiment of a system 200 comprising a component verification module 150. In certain embodiments, the component verification module 150 runs component-level verification testing against tangible or physical embodiments of the system 200 and/or the components 103a-n of the integrated circuits, chips, devices, and/or other hardware elements in the system 200 using a tester device, and/or using a simulation of the system 200 to test the design, operations, and/or behavior of the various components 103a-n of the system 200, as described below. In certain embodiments, at least a portion of the component verification module 150 is located on the computing device 110, and/or is communicatively coupled to the computing device 110 via the network 115.

The component verification module 150 may be part of and/or in communication with one or more of a non-volatile memory controller 124, a non-volatile memory media controller 126, a device driver or storage management layer (SML) 130, or the like. The component verification module 150 may operate on a non-volatile memory system 102 of a computing device 110, which may comprise a processor 111, volatile memory 112, and a communication interface 113. The processor 111 may comprise one or more central processing units, one or more general-purpose processors, one or more application-specific processors, one or more virtual processors (e.g., the computing device 110 may be a virtual machine operating within a host), one or more processor cores, or the like. The communication interface 113 may comprise one or more network interfaces configured to communicatively couple the computing device 110 and/or non-volatile memory controller 124 to a communication network 115, such as an Internet Protocol network, a Storage Area Network, or the like.

The computing device 110 may further comprise a non-transitory, computer readable storage media 114. The computer readable storage media 114 may comprise executable instructions configured to cause the computing device 110 (e.g., processor 111) to perform steps of one or more of the methods disclosed herein. Alternatively, or in addition, the component verification module 150 may be embodied as one or more computer readable instructions stored on the non-transitory storage media 114.

In one embodiment, the component verification module 150 may comprise executable software code, such as a device driver, SML 130, or the like, stored on the computer readable storage media 114 for execution on the processor 111. In another embodiment the component verification module 150 may comprise logic hardware of one or more non-volatile memory devices 120, such as a non-volatile memory media controller 126, a non-volatile memory controller 124, a device controller, a field-programmable gate array (FPGA) or other programmable logic, firmware for an FPGA or other programmable logic, microcode for execution on a microcontroller, an application-specific integrated circuit (ASIC), or the like. In a further embodiment, the component verification module 150 may include a combination of both executable software code and logic hardware.

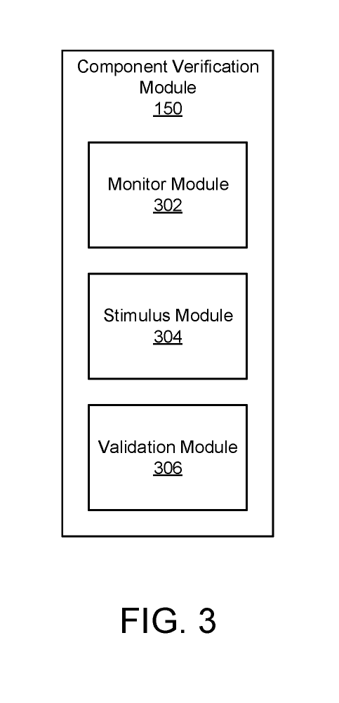

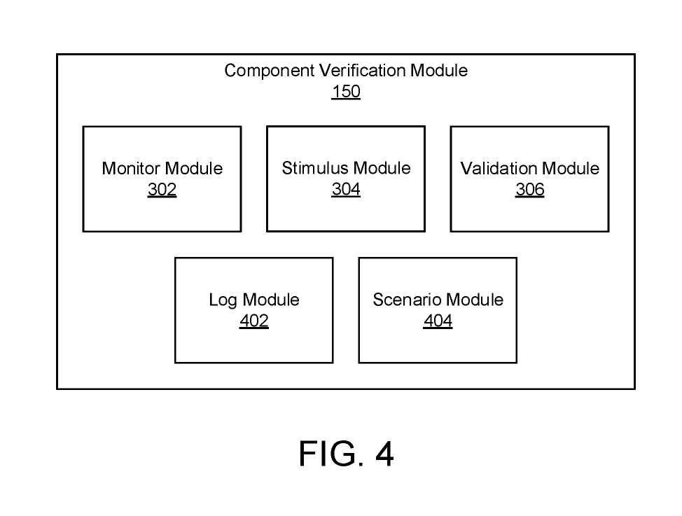

In one embodiment, the component verification module 150 is configured to receive storage requests from the SML 130 via a bus 125 or the like for testing the components 103a-n that are part of the storage system of the system 200. The component verification module 150 may be further configured to transfer data to/from the SML 130 and/or storage clients 116 via the bus 125. Accordingly, the component verification module 150, in some embodiments, may comprise and/or be in communication with one or more direct memory access (DMA) modules, remote DMA modules, bus controllers, bridges, buffers, and so on to facilitate the transfer of storage requests and associated data. In another embodiment, the component verification module 150 may receive storage requests as an API call from a storage client 116, as an IO-CTL command, or the like. The component verification module 150 is described in greater detail below with regard to FIGS. 3 and 4.

According to various embodiments, a non-volatile memory controller 124 comprising the component verification module 150 (e.g., for testing the components 103a-n of the memory devices 120) may manage one or more non-volatile memory devices 120. The non-volatile memory device(s) 120 may comprise recording, memory, and/or storage devices, such as solid-state storage device(s), that are arranged and/or partitioned into a plurality of addressable media storage locations. As used herein, a media storage location refers to any physical unit of memory (e.g., any quantity of physical storage media on a non-volatile memory device 120). Memory units may include, but are not limited to: pages, memory divisions, erase blocks, sectors, blocks, collections or sets of physical storage locations (e.g., logical pages, logical erase blocks, described below), or the like.

The non-volatile memory controller 124 may comprise an SML 130, which may present a logical address space 134 to one or more storage clients 116. One example of an SML is the Virtual Storage Layer® of SanDisk Corporation of Milpitas, Calif. Alternatively, each non-volatile memory device 120 may comprise a non-volatile memory media controller 126, which may present a logical address space 134 to the storage clients 116. As used herein, a logical address space 134 refers to a logical representation of memory resources. The logical address space 134 may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like.

The SML 130 may maintain metadata 135, such as a forward index, to map logical addresses of the logical address space 134 to media storage locations on the non-volatile memory device(s) 120. The SML 130 may provide for arbitrary, any-to-any mappings from logical addresses to physical storage resources. As used herein, an “any-to any” mapping may map any logical address to any physical storage resource. Accordingly, there may be no pre-defined and/or pre-set mappings between logical addresses and particular, media storage locations and/or media addresses. As used herein, a media address refers to an address of a memory resource that uniquely identifies one memory resource from another to a controller that manages a plurality of memory resources. By way of example, a media address includes, but is not limited to: the address of a media storage location, a physical memory unit, a collection of physical memory units (e.g., a logical memory unit), a portion of a memory unit (e.g., a logical memory unit address and offset, range, and/or extent), or the like. Accordingly, the SML 130 may map logical addresses to physical data resources of any size and/or granularity, which may or may not correspond to the underlying data partitioning scheme of the non-volatile memory device(s) 120. For example, in some embodiments, the non-volatile memory controller 124 is configured to store data within logical memory units that are formed by logically combining a plurality of physical memory units, which may allow the non-volatile memory controller 124 to support many different virtual memory unit sizes and/or granularities.

As used herein, a logical memory element refers to a set of two or more non-volatile memory elements that are or are capable of being managed in parallel (e.g., via an I/O and/or control bus). A logical memory element may comprise a plurality of logical memory units, such as logical pages, logical memory divisions (e.g., logical erase blocks), and so on. As used herein, a logical memory unit refers to a logical construct combining two or more physical memory units, each physical memory unit on a respective non-volatile memory element in the respective logical memory element (e.g., each non-volatile memory element being accessible in parallel). As used herein, a logical memory division refers to a set of two or more physical memory divisions, each physical memory division on a respective non-volatile memory element in the respective logical memory element.

The logical address space 134 presented by the SML 130 may have a logical capacity, which may correspond to the number of available logical addresses in the logical address space 134 and the size and/or granularity of the data referenced by the logical addresses. For example, the logical capacity of a logical address space 134 comprising 2^{∧}32 unique logical addresses, each referencing 2048 bytes (2 KiB) of data may be 2^{∧}43 bytes. As used herein, a kibibyte (KiB) refers to 1024 bytes. In some embodiments, the logical address space 134 may be thinly provisioned. As used herein, a “thinly provisioned” logical address space 134 refers to a logical address space 134 having a logical capacity that exceeds the physical capacity of the underlying non-volatile memory device(s) 120. For example, the SML 130 may present a 64-bit logical address space 134 to the storage clients 116 (e.g., a logical address space 134 referenced by 64-bit logical addresses), which may exceed the physical capacity of the underlying non-volatile memory devices 120. The large logical address space 134 may allow storage clients 116 to allocate and/or reference contiguous ranges of logical addresses, while reducing the chance of naming conflicts. The SML 130 may leverage the any-to-any mappings between logical addresses and physical storage resources to manage the logical address space 134 independently of the underlying physical storage devices 120. For example, the SML 130 may add and/or remove physical storage resources seamlessly, as needed, and without changing the logical addresses used by the storage clients 116.

The non-volatile memory controller 124 may be configured to store data in a contextual format. As used herein, a contextual format refers to a self-describing data format in which persistent contextual metadata is stored with the data on the physical storage media 122. The persistent contextual metadata provides context for the data with which it is stored. In certain embodiments, the persistent contextual metadata uniquely identifies the data with which the persistent contextual metadata is stored. For example, the persistent contextual metadata may uniquely identify a sector or block of data owned by a storage client 116 from other sectors or blocks of data owned by the storage client 116. In a further embodiment, the persistent contextual metadata identifies an operation that is performed on the data. In a further embodiment, the persistent contextual metadata identifies a sequence of operations performed on the data. In a further embodiment, the persistent contextual metadata identifies security controls, a data type, or other attributes of the data. In a certain embodiment, the persistent contextual metadata identifies at least one of a plurality of aspects, including data type, a unique data identifier, an operation, and a sequence of operations performed on the data.

The persistent contextual metadata may include, but is not limited to: a logical address of the data, an identifier of the data (e.g., a file name, object id, label, unique identifier, or the like), reference(s) to other data (e.g., an indicator that the data is associated with other data), a relative position or offset of the data with respect to other data (e.g., file offset, etc.), data size and/or range, and the like. The contextual data format may comprise a packet format comprising a data segment and one or more headers. Alternatively, a contextual data format may associate data with context information in other ways (e.g., in a dedicated index on the non-volatile memory media 122, a memory division index, or the like).

In some embodiments, the contextual data format may allow data context to be determined and/or reconstructed based upon the contents of the non-volatile memory media 122, and independently of other metadata, such as the arbitrary, any-to-any mappings discussed above. Since the media location of data is independent of the logical address of the data, it may be inefficient or impossible to determine the context of data based solely upon the media location or media address of the data. Storing data in a contextual format on the non-volatile memory media 122 may allow data context to be determined without reference to other metadata. For example, the contextual data format may allow the metadata to be reconstructed based only upon the contents of the non-volatile memory media 122 (e.g., reconstruct the any-to-any mappings between logical addresses and media locations).

In some embodiments, the non-volatile memory controller 124 may be configured to store data on one or more asymmetric, write-once media 122, such as solid-state storage media. As used herein, a “write once” storage medium refers to a storage medium that is reinitialized (e.g., erased) each time new data is written or programmed thereon. As used herein, an “asymmetric” storage medium refers to a storage medium 122 having different latencies for different storage operations. Many types of solid-state storage media are asymmetric; for example, a read operation may be much faster than a write/program operation, and a write/program operation may be much faster than an erase operation (e.g., reading the media may be hundreds of times faster than erasing, and tens of times faster than programming the media).

The memory media 122 may be partitioned into memory divisions that can be erased as a group (e.g., erase blocks) in order to, inter alia, account for the asymmetric properties of the media 122 or the like. As such, modifying a single data segment in-place may require erasing the entire erase block comprising the data, and rewriting the modified data to the erase block, along with the original, unchanged data. This may result in inefficient “write amplification,” which may excessively wear the media 122. Therefore, in some embodiments, the non-volatile memory controller 124 may be configured to write data out-of-place. As used herein, writing data “out-of-place” refers to writing data to different media storage location(s) rather than overwriting the data “in-place” (e.g., overwriting the original physical location of the data). Modifying data out-of-place may avoid write amplification, since existing, valid data on the erase block with the data to be modified need not be erased and recopied. Moreover, writing data out-of-place may remove erasure from the latency path of many storage operations (e.g., the erasure latency is no longer part of the critical path of a write operation).

The non-volatile memory controller 124 may comprise one or more processes that operate outside of the regular path for servicing of storage operations (e.g., the “path” for performing a storage operation and/or servicing a storage request). As used herein, the “path for servicing a storage request” or “path for servicing a storage operation” (also referred to as the “critical path”) refers to a series of processing operations needed to service the storage operation or request, such as a read, write, modify, or the like. The path for servicing a storage request may comprise receiving the request from a storage client 116, identifying the logical addresses of the request, performing one or more storage operations on non-volatile memory media 122, and returning a result, such as acknowledgement or data. Processes that occur outside of the path for servicing storage requests may include, but are not limited to: a groomer, de-duplication, and so on. These processes may be implemented autonomously and in the background, so that they do not interfere with or impact the performance of other storage operations and/or requests. Accordingly, these processes may operate independent of servicing storage requests.

In some embodiments, the non-volatile memory controller 124 comprises a groomer, which is configured to reclaim memory divisions (e.g., logical or physical erase blocks) for reuse, using a garbage collection or other storage capacity recovery process. The write out-of-place paradigm implemented by the non-volatile memory controller 124 may result in obsolete or invalid data remaining on the non-volatile memory media 122. For example, overwriting data X with data Y may result in storing Y on a new memory division (e.g., rather than overwriting X in place), and updating the any-to-any mappings of the metadata to identify Y as the valid, up-to-date version of the data. The obsolete version of the data X may be marked as invalid, but may not be immediately removed (e.g., erased), since, as discussed above, erasing X may involve erasing an entire memory division, which is a time-consuming operation and may result in write amplification. Similarly, data that is no longer is use (e.g., deleted or trimmed data) may not be immediately removed. The non-volatile memory media 122 may accumulate a significant amount of invalid data.

A groomer process may operate outside of the critical path for servicing storage operations. The groomer process may reclaim memory divisions so that they can be reused for other storage operations. As used herein, reclaiming a memory division refers to erasing the memory division so that new data may be stored/programmed thereon. Reclaiming a memory division may comprise relocating valid data on the memory division to a new location. The groomer may identify memory divisions for reclamation based upon one or more factors, which may include, but are not limited to: the amount of invalid data in the memory division, the amount of valid data in the memory division, wear on the memory division (e.g., number of erase cycles), time since the memory division was programmed or refreshed, and so on.

The non-volatile memory controller 124 may be further configured to store data in a log format. As described above, a log format refers to a data format that defines an ordered sequence of storage operations performed on a non-volatile memory media 122. In some embodiments, the log format comprises storing data in a pre-determined sequence of media addresses of the non-volatile memory media 122 (e.g., within sequential pages and/or erase blocks of the media 122). The log format may further comprise associating data (e.g., each packet or data segment) with respective sequence indicators. The sequence indicators may be applied to data individually (e.g., applied to each data packet) and/or to data groupings (e.g., packets stored sequentially on a memory division, such as an erase block). In some embodiments, sequence indicators may be applied to memory divisions when the memory divisions are reclaimed (e.g., erased), as described above, and/or when the memory divisions are first used to store data.

In some embodiments the log format may comprise storing data in an “append only” paradigm. The non-volatile memory controller 124, using the log storage module 137 described below or the like, may maintain a current append point at a media address of the non-volatile memory device 120. The append point may be a current memory division and/or offset within a memory division. Data may then be sequentially appended from the append point. The sequential ordering of the data, therefore, may be determined based upon the sequence indicator of the memory division of the data in combination with the sequence of the data within the memory division. Upon reaching the end of a memory division, the non-volatile memory controller 124 may identify the “next” available memory division (e.g., the next memory division that is initialized and ready to store data). The groomer may reclaim memory divisions comprising invalid, stale, and/or deleted data, to ensure that data may continue to be appended to the media log.

The log format described herein may allow valid data to be distinguished from invalid data based upon the contents of the non-volatile memory media 122, and independently of other metadata. As discussed above, invalid data may not be removed from the non-volatile memory media 122 until the memory division comprising the data is reclaimed. Therefore, multiple “versions” of data having the same context may exist on the non-volatile memory media 122 (e.g., multiple versions of data having the same logical addresses). The sequence indicators associated with the data may be used to distinguish invalid versions of data from the current, up-to-date version of the data; the data that is the most recent in the log is the current version, and previous versions may be identified as invalid.

The storage management layer 130 may be configured to provide storage services to one or more storage clients 116. The storage clients 116 may include local storage clients 116 operating on the computing device 110 and/or remote, storage clients 116 accessible via the network 115 and/or network interface 113. The storage clients 116 may include, but are not limited to: operating systems, file systems, database applications, server applications, kernel-level processes, user-level processes, applications, and the like.

The storage management layer 130 comprises and/or is communicatively coupled to one or more non-volatile memory devices 120. The one or more non-volatile memory devices 120 may include different types of non-volatile memory devices including, but not limited to: solid-state storage devices, hard drives, SAN storage resources, or the like. The one or more non-volatile memory devices 120 may comprise one or more respective non-volatile memory media controllers 126 and non-volatile memory media 122. As illustrated in FIG. 1, The SML 130 may provide access to the one or more non-volatile memory devices 120 via a traditional block I/O interface 131. Additionally, the SML 130 may provide access to enhanced functionality (e.g., a large, virtual address space 134) through the SML interface 132. The metadata 135 may be used to manage and/or track storage operations performed through any of the Block I/O interface 131, SML interface 132, cache interface 133, or other, related interfaces.

The cache interface 133 may expose cache-specific features accessible via the storage management layer 130. Also, in some embodiments, the SML interface 132 presented to the storage clients 116 provides access to data transformations implemented by the one or more non-volatile memory devices 120 and/or the one or more non-volatile memory media controllers 126.

The SML 130 may provide storage services through one or more interfaces, which may include, but are not limited to: a block I/O interface, an extended storage management layer interface, a cache interface, and the like. The SML 130 may present a logical address space 134 to the storage clients 116 through one or more interfaces. As discussed above, the logical address space 134 may comprise a plurality of logical addresses, each corresponding to respective media locations the on one or more non-volatile memory devices 120. The SML 130 may maintain metadata 135 comprising any-to-any mappings between logical addresses and media locations, as described above.

The SML 130 may further comprise a log storage module 137 that is configured to store data in a contextual, log format. The contextual, log data format may comprise associating data with persistent contextual metadata, such as the logical address of the data, or the like. The contextual, log format may further comprise associating data with respective sequence identifiers on the non-volatile memory media 122, which define an ordered sequence of storage operations performed on the one or more non-volatile memory devices 120, as described above.

The SML 130 may further comprise a non-volatile memory device interface 139 configured to transfer data, commands, and/or queries to the one or more non-volatile memory devices 120 over a bus 125, which may include, but is not limited to: a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network 115, Infiniband, SCSI RDMA, or the like. The non-volatile memory device interface 139 may communicate with the one or more non-volatile memory devices 120 using input-output control (IO-CTL) command(s), IO-CTL command extension(s), remote direct memory access, or the like.

The communication interface 113 may comprise one or more network interfaces configured to communicatively couple the computing device 110 and/or the non-volatile memory controller 124 to a network 115 and/or to one or more remote, network-accessible storage clients 116. The storage clients 116 may include local storage clients 116 operating on the computing device 110 and/or remote, storage clients 116 accessible via the network 115 and/or the network interface 113. The non-volatile memory controller 124 comprises one or more non-volatile memory devices 120. Although FIG. 1 depicts a single non-volatile memory device 120, the disclosure is not limited in this regard and could be adapted to incorporate any number of non-volatile memory devices 120.

The non-volatile memory device 120 may comprise non-volatile memory media 122, which may include but is not limited to: NAND flash memory, NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (SONOS), resistive RAM (RRAM), programmable metallization cell (PMC), conductive-bridging RAM (CBRAM), magneto-resistive RAM (MRAM), dynamic RAM (DRAM), phase change RAM (PRAM or PCM), magnetic storage media (e.g., hard disk, tape), optical storage media, or the like. While the non-volatile memory media 122 is referred to herein as “memory media,” in various embodiments, the non-volatile memory media 122 may more generally comprise a non-volatile recording media capable of recording data, which may be referred to as a non-volatile memory media, a non-volatile storage media, or the like. Further, the non-volatile memory device 120, in various embodiments, may comprise a non-volatile recording device, a non-volatile memory device, a non-volatile storage device, or the like.

The non-volatile memory media 122 may comprise one or more non-volatile memory elements 123, which may include, but are not limited to: chips, packages, planes, die, and the like. A non-volatile memory media controller 126 may be configured to manage storage operations on the non-volatile memory media 122, and may comprise one or more processors, programmable processors (e.g., field-programmable gate arrays), or the like. In some embodiments, the non-volatile memory media controller 126 is configured to store data on and/or read data from the non-volatile memory media 122 in the contextual, log format described above, and to transfer data to/from the non-volatile memory device 120, and so on.

The non-volatile memory media controller 126 may be communicatively coupled to the non-volatile memory media 122 by way of a bus 127. The bus 127 may comprise an I/O bus for communicating data to/from the non-volatile memory elements 123. The bus 127 may further comprise a control bus for communicating addressing and other command and control information to the non-volatile memory elements 123. In some embodiments, the bus 127 may communicatively couple the non-volatile memory elements 123 to the non-volatile memory media controller 126 in parallel. This parallel access may allow the non-volatile memory elements 123 to be managed as a group, forming a logical memory element 129. As discussed above, the logical memory element may be partitioned into respective logical memory units (e.g., logical pages) and/or logical memory divisions (e.g., logical erase blocks). The logical memory units may be formed by logically combining physical memory units of each of the non-volatile memory elements. For example, if the non-volatile memory media 122 comprises twenty-five (25) non-volatile memory elements, each logical memory unit may comprise twenty-five (25) pages (e.g., a page of each element of non-volatile memory media 122).

The non-volatile memory controller 124 may comprise an SML 130 and the non-volatile memory media controller 126. The SML 130 may provide storage services to the storage clients 116 via one or more interfaces 131, 132, and/or 133. In some embodiments, the SML 130 provides a block-device I/O interface 131 through which storage clients 116 perform block-level I/O operations. Alternatively, or in addition, the SML 130 may provide a storage management layer (SML) interface 132, which may provide other storage services to the storage clients 116. In some embodiments, the SML interface 132 may comprise extensions to the block device interface 131 (e.g., storage clients 116 may access the SML interface 132 through extensions to the block device interface 131). Alternatively, or in addition, the SML interface 132 may be provided as a separate API, service, and/or library. The SML 130 may be further configured to provide a cache interface 133 for caching data using the non-volatile memory system 102.

As described above, the SML 130 may present a logical address space 134 to the storage clients 116 (e.g., through the interfaces 131, 132, and/or 133). The SML 130 may maintain metadata 135 comprising any-to-any mappings between logical addresses in the logical address space 134 and media locations on the non-volatile memory device 120. The metadata 135 may comprise a logical-to-physical mapping structure with entries that map logical addresses in the logical address space 134 and media locations on the non-volatile memory device 120. The logical-to-physical mapping structure of the metadata 135, in one embodiment, is sparsely populated, with entries for logical addresses for which the non-volatile memory device 120 stores data and with no entries for logical addresses for which the non-volatile memory device 120 does not currently store data. The metadata 135, in certain embodiments, tracks data at a block level, with the SML 130 managing data as blocks.

The non-volatile memory system 102 may further comprise a log storage module 137, which, as described above, may be configured to store data on the non-volatile memory device 120 in a contextual, log format. The contextual, log data format may comprise associating data with a logical address on the non-volatile memory media 122. The contextual, log format may further comprise associating data with respective sequence identifiers on the non-volatile memory media 122, which define an ordered sequence of storage operations performed on the non-volatile memory media 122, as described above. The non-volatile memory controller 124 may further comprise a non-volatile memory device interface 139 that is configured to transfer data, commands, and/or queries to the non-volatile memory media controller 126 over a bus 125, as described above.

FIG. 3 depicts one embodiment of a module for stimulus generation for component-level verification. In one embodiment, the module 300 includes an instance of a component verification module 150. The component verification module 150, in certain embodiments, includes a monitor module 302, a stimulus module 304, and a validation module 306, which are described in more detail below.

The monitor module 302, in one embodiment, is configured to monitor, detect, identify, and/or the like one or more internal signals for one or more components 103a-n, sub-units, execution elements, and/or the like of an ICDUT 101, e.g., a chip, an integrated circuit, or other hardware logic device during full-chip verification process 105 of the ICDUT 101. For instance, in one embodiment, while the full-chip verification process 105 is testing one or more operations, behaviors, functions, or the like of the ICDUT 101, the monitor module 302 may monitor the signals that are input and/or output from various components 103a-n of the ICDUT 101 that is being tested. As described above, a component 103a-n includes modules, sub-units, execution elements, and/or the like that are configured to perform various operations, functions, steps, instructions, commands, and/or the like of the ICDUT 101 that is being tested.

The monitor module 302, in one embodiment, monitors the internal signals associated with the components 103a-n of the ICDUT 101 by snooping, sniffing, reading, intercepting, and/or the like feedback from the full-chip verification process 105. For instance, the full-chip verification process 105 may generate one or more log files, or streams of log data, and the monitor module 302 may read the log files after or at the same time as they are generated and/or snoop data from the stream of log data. In another embodiment, the monitor module 302 may be communicatively coupled to the components 103a-n of the ICDUT 101 and may receive data associated with one or more signals that the components 103a-n input and/or output in response to the components 103a-n receiving input signals and/or sending output signals. In certain embodiments, the monitor module 302 is communicatively coupled to the ICDUT 101 and receives data associated with the various signals that are sent and received internally within the ICDUT 101 and/or between the various components 103a-n of the ICDUT 101.

In certain embodiments, the ICDUT 101 and/or the various components 103a-n of the ICDUT 101 provides an application programming interface (“API”) or other interface for communicating with the ICDUT 101 and/or the components 103a-n of the ICDUT 101. The interface may provide data associated with a component type, a mode that the ICDUT 101 and/or the components 103a-n are operating in (e.g., read, write, and/or the like), the sender of a received signal, the recipient of a sent signal, the type of signal, data associated with the signal, clock information when a signal is receives and/or sent, the external signals that were received and/or sent during the full-chip verification process 105, an identifier for the components 103a-n that received and/or sent a signal, timing information/signals that are associated with receiving and/or sending a signal, and/or the like.

In certain embodiments, the stimulus module 304 is configured to generate one or more stimuli 104 (e.g., conditions, properties, and/or the like) for triggering the one or more internal signals during verification of the one or more components 103a-n. For instance, sometime after the full-chip verification process 105 is complete, the various components 103a-n of the ICDUT 101 may be independently tested to verify the different operations, modes, functions, and/or the like of the components 103a-n. In order to perform validation testing on the components 103a-n, the stimulus module 304 generates stimuli 104 for triggering various signals, commands, or the like that may cause the components 103a-n to perform various actions, functions, instructions, and/or the like.

The stimulus module 304 may generate the stimulus 104 for performing component-level testing based at least in part on feedback or results from the full-chip verification process 105. For example, during and/or after the full-chip verification process 105 validates a read operation for a non-volatile memory device 120, such as a flash memory device, the stimulus module 304 may use the internal signal information that the monitor module 302 tracks to determine various triggers, signals, modes, and/or the like that trigger the internal signals that cause a particular component 103a-n to perform an action during the read operation. A component 103a-n, for instance, may be configured to copy data from the non-volatile memory device 120 to a cache or other volatile memory. Other components 103a-n may be configured to serialize the data, encrypt the data, compress the data, perform error correcting algorithms on the data, and/or the like. The stimulus module 304 may determine the triggers, signals, modes, variables, parameters, conditions, dependencies, and/or the like, and/or various values of the foregoing, which cause a component 103a-n to perform a particular action, and may generate stimuli 104 that cause the component 103a-n to perform the action without performing a full-chip verification process 105. The stimulus module 304 may also generate stimuli 104 for testing components 103a-n based on system information (e.g. workload information, processing information, system configuration, system temperature, and/or the like), information provided by a user (e.g., a system administrator, a quality assurance tester, and/or the like), and/or the like.

The stimuli 104, for example, may include setting variable values, setting modes of the ICDUT 101 and/or the components 103a-n, configuring clock timing values or settings, setting dependency values, calling functions and predetermined times, receiving and/or sending messages or data from other components 103a-n, setting external signal values (e.g., signals that act on the ICDUT 101 and not directly on the component 103a-n), and/or the like. The stimulus module 304 may set the values for the various stimuli 104 in a log file that can be read by a script or other component verification process 108. In a further embodiment, the stimulus module 304 generates a script that automatically sets the values for the stimuli 104 and performs verification testing as part of the component verification process 108.

In one embodiment, the stimulus module 304 may further generate stimuli 109 for testing one or more operations, behaviors, and/or the like of the ICDUT 101 based on the results of, and/or during, the component verification process 108. In such an embodiment, the stimulus module 304 generates stimuli 109, e.g., stimuli that cause various signals, modes, clock settings, and/or the like to be set during the full-chip verification process 105 in order to test different operations or sub-operations of the ICDUT 101. For example, if it is determined during component verification testing 108 that a component 103a-n requires signals A and B to be triggered to perform a particular action that is part of a larger operation performed at the ICDUT 101 level, such as a write or program operation on a non-volatile storage device 120, then the stimulus module 304 may generate ICDUT stimuli 109 to ensure that signals A and B are triggered during the write operation for that particular component 103a-n. In such an embodiment, the ICDUT stimuli 109 may include setting various modes, settings, parameters, variables, pins, electrical connections, and/or the like of the ICDUT 101.

In one embodiment, the validation module 306 is configured to verify an operating state of the one or more components 103a-n of the ICDUT 101 in response to the generated stimuli 104. The operating state, as used herein, describes an execution state such as an operation, a behavior, and/or the like of a component 103a-n. For example, the operating state may describe how the component 103a-n operates as part of a larger operation performed by the ICDUT 101, such as a read operation, a write operation, a garbage collection operation, and/or the like. The validation module 306, in one embodiment, is configured to determine whether a component 103a-n performs as expected based on the stimuli 104 that the stimulus module 304 generates according to the feedback from the full-chip verification process 105.

For example, in order to verify that an error component that is configured for performing error correction on data that is read from an ICDUT 101 that is embodied as a non-volatile memory device 120 performs as expected, designed, and/or intended, the monitor module 302 may monitor the internal signals associated with the error component during the full-chip verification process 105 of the ICDUT 101 to determine which triggers, signals, variables, conditions, parameters, modes, and/or the like are associated with the error component during a read operation on the ICDUT 101. Accordingly, based at least in part on the results of the full-chip verification process 105, the stimulus module 304 generates stimuli 104 for triggering the various internal signals that act upon or are received by the error component during the read operation for the ICDUT 101, and which may cause the error component to perform one or more operations or actions, such as correcting errors with the read data.

For instance, the stimulus module 304 may determine that signals A and B were received by the error component during read operation testing on the ICDUT 101. The stimulus module 304 may then determine a state of the computing device 110, a state of the ICDUT 101, parameter settings, dependency settings, mode settings, clock settings, and/or the like when the error component received signals A and B. The stimulus module 304 may then generate stimuli 104 for triggering signals A and B during component verification testing of the error component, such as setting variable or parameter values, determining commands, functions, and/or instructions that trigger signals A and B, setting clock values, and/or the like.

Continuing with the example above, the validation module 306 may perform validation testing (e.g., design verification testing) on the error component by generating tests, assertions, scripts, and/or the like that may comprise a sequence of instructions, functions, commands, and/or the like, and corresponding values for settings, parameters, variables, dependencies, and/or the like that are used by the instructions, functions, commands, and/or the like based on the stimuli 104 generated by the stimulus module 304. In one embodiment, the validation module 306 generates various tests, assertions, scripts, and/or the like for testing a particular component 103a-n according to a universal verification methodology (“UVM”). As used herein, UVM is a methodology for verifying integrated circuit designs, both physical hardware designs and/or simulated hardware designs of integrated circuits, which includes a collection of APIs, specifications, standards, guidelines, and/or the like for creating integrated circuit design verification environments.

For instance, the validation module 306 may generate and execute a series of scenarios, tests (UVM tests, for example), and/or the like that include commands, sequences, assertions, and/or the like for testing or verifying an operating state, one or more behaviors or actions, and/or the like of a particular component 103a-n. The validation module 306 may use, reference, trigger, and/or the like the stimuli 104 that the stimulus module 304 generates to design, implement, execute, and/or the like the generated verification tests that are run against the components 104a-n.

FIG. 4 depicts one embodiment of a module for stimulus generation for component-level verification. In one embodiment, the module 400 includes an instance of a component verification module 150. The component verification module 150, in certain embodiments, includes a monitor module 302, a stimulus module 304, and a validation module 306, which may be substantially similar to the monitor module 302, the stimulus module 304, and the validation module 306 described above with reference to FIG. 3. Furthermore, in one embodiment, the component verification module 150 depicted in FIG. 4 includes one or more of a log module 402 and a scenario module 404, which are described in more detail below.

The log module 402, in one embodiment, is configured to collect, track, store, and/or the like feedback from the full-chip verification process 105 by sampling information associated with the one or more components 103a-n of the ICDUT 101 during the full-chip verification process 105. The sampled information, as described above, may include signal information, mode information (e.g., the mode of the ICDUT 101 and/or the component 103a-n at a particular time), clock information (e.g., timing information, timestamps when certain signals are received and/or sent), conditions, dependencies, relationships between components 103a-n and/or signals, and/or the like for the ICDUT 101 and/or the component 103a-n. In certain embodiments, the log module 402 is communicatively coupled to the monitor module 302 and receives at least a portion of the sampled information from the monitor module 302 while the monitor module 302 monitors the internal signals associated with the components 103a-n.

In one embodiment, the log module 402 writes the sampled information from the full-chip verification process 105 to a full-chip verification log file. In other words, the log module 402 writes the sampled information from the full-chip verification process 105 to a single log file that comprises information for each component 103a-n that is a part of the ICDUT 101, each component 103a-n that was activated or enabled during the full-chip verification process 105 of the ICDUT 101, and/or the like. The log file may comprise a text file, a structured document file (e.g., an extensible markup language file (“XML”)), and/or the like. The log file may be structured, outlined, separated, organized, and/or the like by component 103a-n, by signal, by mode, by clock timing, and/or the like.

In certain embodiments, the log module 402 generates different component-level log files for each of the components 103a-n based on the sampled information from the full-chip verification process 105. For instance, the log module 402 may analyze the full-chip verification log file for information related to each component 103a-n of the ICDUT 101, and write information associated with a particular component 103a-n to a log file specifically for that component 103a-n.

In some embodiments, the log module 402 writes the sampled information to a database 119, e.g., a relational or NoSQL database, or some other data store. The log module 402 may store one or more log files in the database 119 and/or may store the sampled information directly in the database 119 without writing the sampled information to a log file. In certain embodiments, the log module 402 populates separate tables in a database, or other data store, that are each assigned to or associated with a particular component 103a-n of the ICDUT 101 with information that is sampled from the full-chip verification process 105 for each component 103a-n, similar to the separate log files described above.

In one embodiment, the log module 402 reads the sampled information for a particular component 103a-n from the full-chip verification log file, from the separate log file for that component, from the database 119, and/or the like in response to a request from the stimulus module 304, the validation module 306, or the like. In certain embodiments, the stimulus module 304 directly opens and reads the log file associated with a component 103a-n, or accesses a database 119 that stores information for that component 103a-n to generate or create stimuli 104 for testing the component 103a-n.

In one embodiment, the scenario module 404 is configured to generate, design, determine, and/or the like one or more coverage scenarios for one or more components 103a-n. As used herein, a coverage scenario comprises a sequence, list, series or the like of actions, commands, signals (external and/or internal), instructions, and/or the like for a particular testing scenario that, when triggered, execute one or more operations of the components 103a-n. For instance, a coverage scenario may be designed to test a particular property, action, operation, and/or the like of a component 103a-n. For example, the scenario module 404 may create a coverage scenario for testing a garbage collection action for a garbage collection component of an ICDUT 101.

In certain embodiments, the scenario module 404 references the stimuli 104 that the stimulus module 304 generates, the log files/data that the log module 402 generates, and/or the like for information from the full-chip verification process 105 and/or other component-level verification processes 108 associated with generating, creating, or designing coverage scenarios for a component 103a-n. The validation module 306, in certain embodiments, executes, runs, or otherwise processes the coverage scenarios, using the stimuli 104, to verify the operating state, behaviors, or other operations of the components 103a-n.

In one embodiment, the scenario module 404 determines one or more internal signals of the coverage scenarios for the components 103a-n that are not triggered during verification of the components 103a-n. For instance, the scenario module 404 may determine that signals A and B were not triggered for a coverage scenario intended to test an operating state of a component 103a-n of an ICDUT 101 during a read operation for the ICDUT 101. In such an embodiment, the scenario module 404 checks the full-verification log file, the log file associated with a component 103a-n, the database 119, and/or the like, to determine which signals were triggered for one or more components 103a-n during the full-chip verification process 105 and cross-references that information with a list, table, and/or the like of signals that should or could be triggered to cause a component 103a-n to perform an action, operation, and/or the like. In such an embodiment, the scenario module 404 maintains a list, database, file, and/or the like of coverage scenarios, and the internal signals that define the coverage scenarios, for each component 103a-n (e.g., where each coverage scenario is for a particular operation, or series of operations that the component 103a-n performs), which may be used or referenced in light of the feedback from the full-chip verification process 105 to determine whether the internal signals that define a particular coverage scenario were triggered during the full-chip verification process 105.

In response to the scenario module 404 determining which internal signals were uncovered, e.g., not triggered or tested, for a component 103a-n during the full-chip verification process 105, the stimulus module 304 may generate stimuli 104 that is intended to trigger the uncovered internal signals during the component verification process 108 based on the feedback from the full-chip verification process 105 described above.

In some embodiments, the scenario module 404 checks the list, database, file, and/or the like of coverage scenarios for a particular component 103a-n after the full-chip verification process 105, after the component verification process 108, and/or the like to determine the number of coverage scenarios that have been triggered, executed, run, or the like for the component 103a-n. In such an embodiment, if the scenario module 404 determines that the number of executed coverage scenarios does not satisfy a coverage threshold for the component 103a-n, the stimulus module 304 may generate or update the component stimuli 104, based on the feedback from the full-chip verification process 105, in an attempt to execute or trigger one or more coverage scenarios that the validation module 306 did not trigger during the component verification process 108.

In such an embodiment, the validation module 306 re-runs or re-executes the component verification process 108 to verify the operating state of the components 103a-n based on the updated or generated component stimuli 104 in an attempt to trigger the untriggered coverage scenarios that the scenario module 404 identified. Thereafter, the scenario module 404 may determine whether the number of coverage scenarios that are triggered during the component verification process 108 satisfies the coverage threshold. The foregoing process of checking whether the number of coverage scenarios satisfies a coverage threshold, refining the stimuli 104, and re-running the component verification process 108 may continue until the coverage threshold is satisfied, until the scenario module 404 determines that the coverage threshold will not be satisfied (e.g., that a limit has been reached), until a predefined number of attempts to satisfy the coverage threshold has been reached, and/or the like.

In one embodiment, the scenario module 404 may review, check, or otherwise analyze the coverage scenarios that were not executed or triggered during the full-chip verification process 105 and/or the component verification process 108 to determine whether the untriggered coverage scenarios are feasible. For instance, the scenario module 404 may determine that a particular coverage scenario is not feasible when the ICDUT 101 is in a particular mode, when a particular signal is triggered, and/or the like. Accordingly, such untriggered coverage scenarios may not execute as designed or expected in light of the generated stimuli 104. The scenario module 404 may mark such untriggered coverage scenarios as invalid so that the coverage scenarios are disregarded in future full-chip and component verification processes 105, 108 based on the particular set of stimuli 104.

In an example embodiment, a particular component 103a-n may be pre-selected for component verification testing, e.g., component A. The monitor module 302 and/or the log module 402 may monitor the internal signals associated with component A during the full-chip verification process 105. The output from the full-chip verification process 105 as it relates to component A may be as follows:

(SAMPLER_time_2789902NS): Signal # NEG_EN # R_CLK # SLC_Pvfy_SGVFY

(SAMPLER_time_2789903NS): Clock # R_CLK # SLC_Pvfy_SGVFY # NEG_EN

(SAMPLER_time_2789903NS): Mode # SLC_Pvfy_SGVFY # R_CLK # NEG_EN

(SAMPLER_time_2904534NS): Signal # PVFYtoPROG # DIS_CLK # SLC_Pvfy_SGVFY

The output above illustrates at least three types of monitoring and data sampling from the full-chip verification process: (1) signal sampling—when an important, flagged, or detected internal signal associated with component A is triggered, the signal is sampled along with the related clock and mode information; (2) mode sampling—when a mode, e.g., read, write, or the like, is enabled on the ICDUT 101, the clock and internal signals are sampled as it relates to component A; and (3) clock sampling—when a clock sequence is triggered, internal signals and mode information is sampled as it relates to component A.

The log module 402 may store the output above as a log file, which may be used to generate stimuli 104 and/or coverage scenarios. For example, the scenario module 404 may use a script to read or parse the log file to generate coverage points or scenarios for verifying different operating states of a component. Example coverage points that the scenario module 404 (or a script executed by the scenario module 404) outputs may be as follows:
// ################# Cover Point 2 clock change ###################### property cover_prop_2( );
@(posedge W_CLK)
   (1′b1)|->p_pumpwait && FSM_PRO;
endproperty
cover_point_2: cover property(cover_prop_2);
// ################# Cover Point 3 mode change ###################### property cover_prop_3( );
@(posedge p_pumpwait)
   (1′b1)|->W_CLK && FSM_PRO;
endproperty
cover_point_3: cover property(cover_prop_3);
// ################# Cover Point 2 clock change ###################### property cover_prop_2( );
@(posedge W_CLK)
   (1′b1)|->p_pumpwait && FSM_PRO;
endproperty
cover_point_2: cover property(cover_prop_2);

Based on the coverage points above, the stimulus module 304 may generate stimuli 104 for triggering the internal signals for the coverage points, based at least in part on the logged information from the full-chip verification process 105, and the validation module 306 executes one or more tests, instructions, commands, and/or the like directed to triggering the coverage points based on the generated stimuli 104.

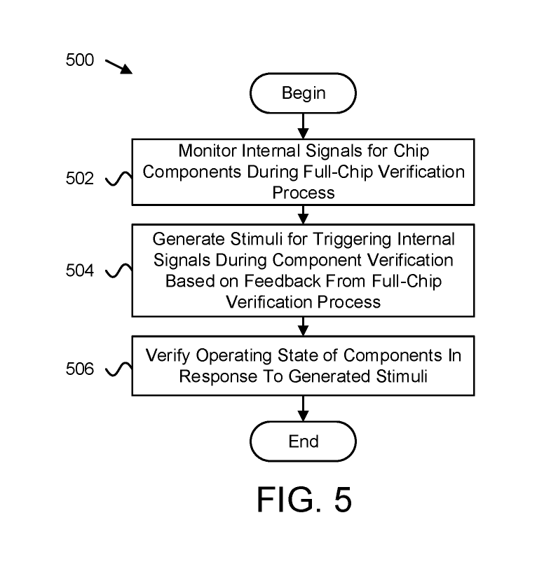

FIG. 5 depicts one embodiment of a method 500 for stimulus generation for component-level verification. In one embodiment, the method 500 begins and the monitor module 302 monitors 502 one or more internal signals for one or more components 103a-n of a chip, e.g., the ICDUT 101, during a full-chip verification process 105. In a further embodiment, the stimulus module 304 generates 504 one or more stimuli 104 for triggering the one or more internal signals during verification of the one or more components 103a-n. The stimuli 104 may be generated based at least in part on feedback from the full-chip verification process 105. In certain embodiments, the validation module 306 verifies 506 an operating state of the one or more components 103a-n in response to the generated stimuli 104. The generated stimuli 104 may trigger the one or more internal signals during verification of the one or more components 103a-n, and the method 500 ends.

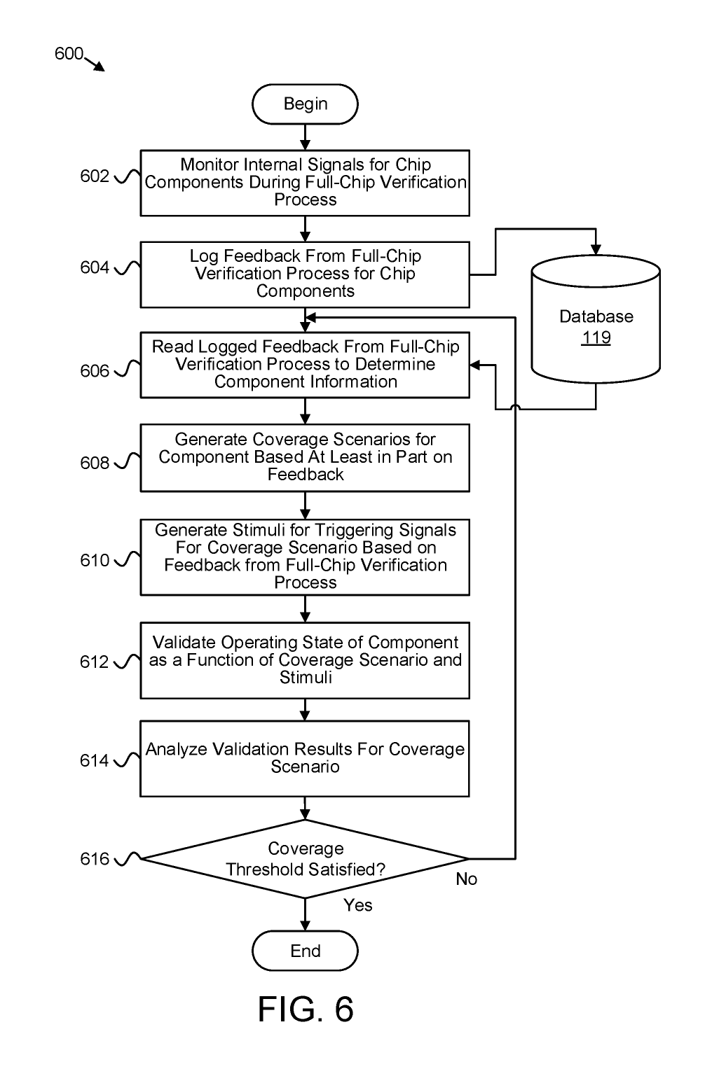

FIG. 6 depicts one embodiment of a method 600 for stimulus generation for component-level verification. In one embodiment, the method 600 begins and the monitor module 302 monitors 602 one or more internal signals for one or more components 103a-n of a chip, e.g., the ICDUT 101, during a full-chip verification process 105. In a further embodiment, the log module 402 logs 604 feedback from the full-chip verification process by sampling information associated with the one or more components 103a-n of the chip during the full-chip verification process 105. In various embodiments, the log module 604 stores the logged feedback in a database 119.

In a further embodiment, the log module 402 and/or the stimulus module 304 reads 606 the logged feedback, e.g., from the database 119, from the full-chip verification process 105 to determine component 103a-n information, such as associated internal signals, modes signals, clock signals, and/or the like for one or more components 103a-n. In certain embodiments, the scenario module 404 generates 608 or designs one or more coverage scenarios (e.g., a series of internal signals for performing an action) for one or more components 103a-n in order to test various operations, behaviors, or the like of the one or more components 103a-n, based at least in part on the logged feedback from the full-chip verification process 105.

In one embodiment, the stimulus module 304 generates 610 one or more stimulus 104 for triggering the one or more internal signals of a coverage scenario for a component 103a-n based on the logged feedback from the full-chip verification process 105. In certain embodiments, the validation module 306 verifies 612 an operating state of the component as a function of the internal signals of the coverage scenario and the stimuli 104 that are used to trigger the internal signals of the coverage scenario.

In one embodiment, the scenario module 404 analyzes 614 the results of the component-level verification process 108 that the validation module 306 performs to determine 616 whether a coverage threshold was satisfied during the component verification process 108. In certain embodiments, the scenario module 404 determines 616 that the coverage threshold is satisfied in response to the number of coverage scenarios that are executed, run, triggered, or the like successfully being greater than or equal to a coverage threshold value. If the scenario module 404 determines 616 that the coverage threshold was not satisfied, then the log module 402 and/or the stimulus module 304 read 606 feedback from the database 119 associated with the full-chip verification process 105 to determine, generate, or update 608, 610 coverage scenarios and stimuli 104 for verifying the operating state of the component 103a-n. Otherwise, if the scenario module 404 determines 616 that the coverage threshold is satisfied, then the method 600 ends.

A means for monitoring internal signals for components 103a-n of a chip during a full-chip verification process, in various embodiments, may include a monitor module 302, a component verification module 150, a processor, an FPGA, an ASIC, a computing device 110, a hardware tester device, other logic hardware, and/or other executable code stored on a computer readable storage medium. Other embodiments may include similar or equivalent means for monitoring internal signals for components 103a-n of a chip during a full-chip verification process.

A means for generating one or more stimuli 104 for triggering the one or more internal signals during verification of the one or more components 103a-n, in various embodiments, may include a stimulus module 304, a component verification module 150, a processor, an FPGA, an ASIC, a computing device 110, a hardware tester device, other logic hardware, and/or other executable code stored on a computer readable storage medium. Other embodiments may include similar or equivalent means for generating one or more stimuli 104 for triggering the one or more internal signals during verification of the one or more components 103a-n.

A means for verifying an operating state of the one or more components 103a-n in response to the generated stimuli 104, in various embodiments, may include a validation module 306, a component verification module 150, a processor, an FPGA, an ASIC, a computing device 110, a hardware tester device, other logic hardware, and/or other executable code stored on a computer readable storage medium. Other embodiments may include similar or equivalent means for verifying an operating state of the one or more components 103a-n in response to the generated stimuli 104.

The present disclosure may be embodied in other specific forms without departing from its spirit or essential characteristics. The described embodiments are to be considered in all respects only as illustrative and not restrictive. The scope of the disclosure is, therefore, indicated by the appended claims rather than by the foregoing description. All changes which come within the meaning and range of equivalency of the claims are to be embraced within their scope.

What is claimed is:

1. A method comprising:
monitoring one or more internal signals for one or more components of a chip during a full-chip verification process;
generating one or more stimuli for triggering the one or more internal signals during verification of the one or more components, the stimuli generated based at least in part on feedback from the full-chip verification process; and
verifying an operating state of the one or more components in response to the generated stimuli, the generated stimuli triggering the one or more internal signals during verification of the one or more components.

2. The method of claim 1, further comprising collecting the feedback from the full-chip verification process by sampling information associated with the one or more components of the chip during the full-chip verification process, the sampled information comprising one or more of signal information, chip mode information, and clock information for one or more of the chip and the one or more components of the chip.

3. The method of claim 2, further comprising writing the sampled information from the full-chip verification process for each of the one or more components to a full-chip verification log file.

4. The method of claim 3, further comprising reading the full-chip verification log file for signal information associated with the one or more components to generate the one or more stimuli for triggering the one or more internal signals during verification of the operating state of the one or more components of the chip.

5. The method of claim 3, further comprising:
generating different component-level log files for each of the one or more components;
analyzing the full-chip verification log file for sampled information associated with a particular component;
writing the sampled information associated with the particular component to the log file for the particular component; and
reading the log file for the particular component for signal information to generate the stimuli for triggering one or more internal signals during verification of the particular component.

6. The method of claim 1, wherein the operating state of the one or more components is defined by one or more coverage scenarios comprising a predefined sequence of internal signals that, when triggered, execute one or more operations of the one or more components.

7. The method of claim 6, further comprising:
determining one or more internal signals of the coverage scenarios for the one or more components that are not triggered during verification of the one or more components; and
generating one or more stimuli to trigger the one or more untriggered internal signals of the coverage scenarios for the one or more components during verification of the one or more components.

8. The method of claim 7, further comprising checking a database of coverage scenarios for each of the one or more components to determine which internal signals define coverage scenarios for the one or more components and which internal signals of the coverage scenarios are not triggered during verification of the one or more components.

9. The method of claim 6, further comprising:
updating the one or more stimuli after verification of the one or more components in response to the number of coverage scenarios that are triggered for the one or more components not satisfying a coverage threshold;
re-running verification of the operating state of the one or more components based on the updated stimuli; and
determining whether the number of coverage scenarios that are triggered during verification of the one or more components based on the updated stimuli satisfies the coverage threshold.

10. The method of claim 6, further comprising disregarding one or more coverage scenarios that are determined to be invalid during verification of the one or more components, the one or more invalid coverage scenarios not executing as expected based on the one or more stimuli generated according to the feedback from the full-chip verification process.

11. The method of claim 1, wherein the stimuli for triggering the one or more internal signals during verification of the one or more components comprises one or more of triggering external signals for the chip, triggering internal signals for the one or more components, setting chip modes, and triggering clock sequences.

12. The method of claim 1, wherein the full-chip verification process and the verification of the one or more components comprise one or more of a design verification process of a simulated version of the chip and the one or more components, and a hardware verification process of a manufactured version of the chip and the one or more components using a hardware tester device.

13. The method of claim 1, further comprising generating one or more external stimuli for the full-chip verification process based at least in part on feedback from the verification of the operating state of the one or more components.

14. An apparatus comprising:
means for detecting one or more signals for one or more sub-units of an integrated circuit (“IC”) during a design verification test of the IC;
means for collecting data during the design verification test of the IC that indicates one or more conditions associated with the IC that trigger the one or more signals for the one or more sub-units; and
means for testing one or more operations of the one or more sub-units in response to triggering the one or more signals for the one or more sub-units based on one or more stimuli generated as a function of the condition data collected during the design verification test of the IC.

15. The apparatus of claim 14, wherein the condition data is collected by sampling data associated with the one or more sub-units of the IC during the design verification test of the IC, the sampled data comprising one or more of signal data, IC mode data, and clock data for one or more of the IC and the one or more sub-units of the IC.

16. The apparatus of claim 15, further comprising means for:
writing the sampled information from the design verification test of the IC for each of the one or more sub-units to an IC verification log file; and
reading the IC verification log file for signal information associated with the one or more sub-units to generate the one or more stimuli for triggering the one or more signals during testing of the one or more operations of the one or more sub-units of the IC.

17. The apparatus of claim 14, wherein the one or more operations of the one or more sub-units are triggered according to coverage scenarios, the coverage scenarios comprising a predefined sequence of signals that, when triggered, produce one or more actions on the one or more sub-units.

18. The apparatus of claim 17, further comprising means for:
determining one or more signals of the coverage scenarios for the one or more sub-units that are not triggered during testing of the one or more sub-units; and
generating one or more stimuli to trigger the one or more untriggered signals of the coverage scenarios for the one or more sub-units during testing of the one or more sub-units.

19. The apparatus of claim 17, further comprising means for;
updating the one or more stimuli after testing the one or more operations of the one or more sub-units in response to the number of coverage scenarios that are triggered for the one or more sub-units not satisfying a coverage threshold;
re-running testing of the one or more operations of the one or more sub-units based on the updated stimuli; and
determining whether the number of coverage scenarios that are triggered during testing of the one or more sub-units based on the updated stimuli satisfies the coverage threshold.

20. A computer program product comprising a computer readable storage medium storing computer usable program code executable to perform operations, the operations comprising:
identifying one or more signals that trigger one or more operations of one or more execution elements of an integrated circuit chip during testing of one or more operations of the integrated circuit chip;
determining one or more properties for triggering the one or more signals for the one or more execution elements based on the results of the testing of the one or more operations of the integrated circuit chip; and
generating one or more scenarios based on the determined properties for triggering one or more signals of the one or more execution elements of the integrated circuit chip to verify one or more operations of the one or more execution elements.
